(19) United States
(12) Patent Application Publication
(10) Pub. No.: US 2011/0007769 A1
(43) Pub. Date: Jan. 13, 2011

(54) LASER DIODE

(75) Inventors: Yuji Masui, Kanagawa (JP); Osamu Maeda, Kanagawa (JP); Rintaro Koda, Tokyo (JP); Takahiro Arakida, Kanagawa (JP); Naoki Jogan, Kanagawa (JP); Kouichi Kondo, Kanagawa (JP)

Correspondence Address: K&L Gates LLP, P. O. BOX 1135, CHICAGO, IL, 60690, US

(73) Assignee: SONY CORPORATION, Tokyo (JP)

(21) Appl. No.: 12/824,377

(22) Filed: Jun. 28, 2010

(30) Foreign Application Priority Data
Jul. 10, 2009 (JP) P2009-164049

(51) Int. Cl. H01S 5/10; H01S 5/00

(52) U.S. Cl. 372/46.013

(57) ABSTRACT

A laser diode includes: a first multilayer film reflecting mirror, an active layer, and a second multilayer film reflecting mirror in this order; and a first oxide narrowing layer and a second oxide narrowing layer. The first oxide narrowing layer is formed close to the active layer, in comparison with the second oxide narrowing layer, includes a first unoxidized region in a middle region in a plane, and includes a first oxidized region on a periphery of the first unoxidized region. The second oxide narrowing layer includes, in a region facing the first unoxidized region, a second unoxidized region having a diameter smaller than that of the first unoxidized region, includes a third unoxidized region in a region not facing the first unoxidized region, and includes a second oxidized region on a periphery of the second unoxidized region and the third unoxidized region.

### CROSS REFERENCES TO RELATED APPLICATIONS

The present application claims priority to Japanese Priority Patent Application JP 2009-164049 filed in the Japan Patent Office on Jul. 10, 2009, the entire content of which is hereby incorporated by reference.

### BACKGROUND

The present application relates to a laser diode emitting laser light in a stacking direction.

A surface emitting laser diode has low power consumption in comparison with an edge emitting laser diode, and is capable of direct modulation. Thus, the surface emitting laser diode has been used as an inexpensive light source for optical communication in recent years.

In the surface emitting laser diode, typically, a columnar mesa formed by stacking a lower DBR layer, a lower spacer layer, an active layer, an upper spacer layer, an upper DBR layer, and a contact layer in this order on a substrate is provided. In one of the lower DBR layer and the upper DBR layer, a current narrowing layer having a structure in which a current injection region is narrowed is provided so as to increase current injection efficiency to the active layer, and to reduce a threshold current. On each of the top face of the mesa and the rear face of the substrate, an electrode is provided. In this laser diode, after a current injected from the electrode is narrowed by the current narrowing layer, the current is injected into the active layer, and thereby light emission is generated by recombination of an electron and a hole. This light is reflected by the lower DBR layer and the upper DBR layer, and a laser oscillation is generated at a predetermined wavelength. The light is emitted as laser light from the top face of the mesa.

In the surface emitting laser diode described above, it is not easy to obtain a beam having high output and a complete-circular shape. In the surface emitting laser diode, the current narrowing diameter is approximately 10 μm, and it is larger than that of the edge emitting laser diode. Thus, the gain difference in a transverse mode is small, and a multimode oscillation is likely to be generated. For example, for the purpose of increasing light output, when a current injected into a light emitting region is increased, a ring shaped high-order transverse mode is oscillated in addition to a complete-circular shaped fundamental transverse mode, and the shape of the beam is disordered. In the surface emitting laser diode, the thickness of the active layer is approximately several tens of nm, the diameter of the light emitting region of the active layer is approximately 10 μm, and the volume of the light emitting region is much smaller than that of the light emitting region of the edge emitting laser diode. Therefore, when the current injected into the light emitting region is increased as described above, the light output is immediately saturated by heat locally generated in the light emitting region, and it is difficult to obtain the large light output even when the current injection amount is simply increased.

Thus, a great number of measures to increase the gain difference in the transverse mode have been proposed from the past. For example, in Japanese Unexamined Patent Publication No. 2002-208755, it is proposed to reduce an aperture diameter of an electrode provided on the top face of a mesa, in comparison with that of an electrode in the existing technique. Further, for example, in Japanese Unexamined Patent Publication No. 2004-253408, it is proposed to provide an oxide narrowing layer one by one on both of p-side and n-side so as to promote the current injection into a middle section, thereby allowing the fundamental transverse mode oscillation to be easily generated.

### SUMMARY

However, in the method of Japanese Unexamined Patent Publication No. 2002-208755, since the light loss in the electrode is large, the process margin is small, and there is an issue that mass productivity is inferior. In the method of Japanese Unexamined Patent Publication No. 2004-253408, since the current constricting is doubly performed, there is an issue that the electricity resistance is increased. Further, in this method, to obtain the fundamental transverse mode oscillation only by the current constricting, it is necessary to reduce the current narrowing diameter to approximately 5 μm. However, in the case where the current narrowing diameter is reduced in this manner, there is an issue that it is difficult to obtain the large light output due to the heat locally generated in the light emitting region.

In view of the foregoing, it is desirable to provide a laser diode capable of obtaining a beam which has high output, and a complete-circular shape.

According to an embodiment, there is provided a laser diode including: a first multilayer film reflecting mirror, an active layer, and a second multilayer film reflecting mirror in this order; and a first oxide narrowing layer and a second oxide narrowing layer. The first oxide narrowing layer is formed close to the active layer, in comparison with the second oxide narrowing layer. The first oxide narrowing layer includes a first unoxidized region in a middle region in a plane, and includes a first oxidized region on a periphery of the first unoxidized region. Meanwhile, the second oxide narrowing layer includes, in a region facing the first unoxidized region, a second unoxidized region having a diameter smaller than that of the first unoxidized region, and includes a third unoxidized region in a region not facing the first unoxidized region. Further, the second oxide narrowing layer includes a second oxidized region on a periphery of the second unoxidized region and the third unoxidized region.

In the laser diode according to an embodiment, in a middle region of the first oxide narrowing layer which is located close to the active layer, the first unoxidized region having a large diameter is formed, and in a middle region of the second oxide narrowing layer which is located away from the active layer, the second unoxidized region having a small diameter is formed. Thereby, a high-order transverse mode oscillation may be suppressed while increasing a volume of a light emitting region of the active layer. Further, in the embodiment of the present invention, the third unoxidized region is formed in a region other than the middle region in the second oxide narrowing layer. Thereby, the third unoxidized region may serve as a current path in the second oxide narrowing layer, and thus it is possible to reduce a resistance value of the second oxide narrowing layer.

According to the laser diode of an embodiment, the first unoxidized region is formed in the first oxide narrowing layer which is located close to the active layer, the second unoxidized region is formed in the second oxide narrowing layer which is located away from the active layer, and the third unoxidized region is formed in the region other than the middle region in the second oxide narrowing layer. Thereby, it is possible to obtain a beam having high output and a complete-circular shape.

Additional features and advantages are described herein, and will be apparent from the following Detailed Description and the figures.

### BRIEF DESCRIPTION OF THE FIGURES

FIG. 1 is a perspective view of a surface emitting laser diode according to a first embodiment.

FIG. 2 is a cross-sectional view of the laser diode of FIG. 1.

FIG. 3 is a cross-sectional view of an oxide narrowing layer for controlling a transverse mode of FIG. 1.

FIGS. 4A and 4B are cross-sectional views for explaining an example of a manufacture process of the laser diode of FIG. 1.

FIGS. 5A and 5B are cross-sectional views for explaining a step subsequent to FIGS. 4A and 4B.

FIG. 6 is a cross-sectional view for explaining a current path and an optical field of the laser diode of FIG. 1.

FIG. 7 is a perspective view of a modification of the laser diode of FIG. 1.

FIG. 8 is a cross-sectional view as viewed from the direction of arrow A-A of the laser diode of FIG. 7.

FIG. 9 is a cross-sectional view as viewed from the direction of arrow B-B of the laser diode of FIG. 7.

FIG. 10 is a cross-sectional view of the oxide narrowing layer for controlling the transverse mode of FIG. 7.

FIG. 11 is a cross-sectional view for explaining the current path and the optical field of the laser diode of FIG. 7.

FIG. 12 is a perspective view of a surface emitting laser diode according to a second embodiment.

FIG. 13 is a cross-sectional view as viewed from the direction of arrow A-A of the laser diode of FIG. 12.

FIG. 14 is a cross-sectional view as viewed from the direction of arrow B-B of the laser diode of FIG. 12.

FIG. 15 is a cross-sectional view of an oxide narrowing layer for controlling a transverse mode of FIG. 12.

FIG. 16 is a cross-sectional view for explaining a current path and an optical field of the laser diode of FIG. 12.

### DETAILED DESCRIPTION

The present application will be described in detail below with reference to the figures according to an embodiment.

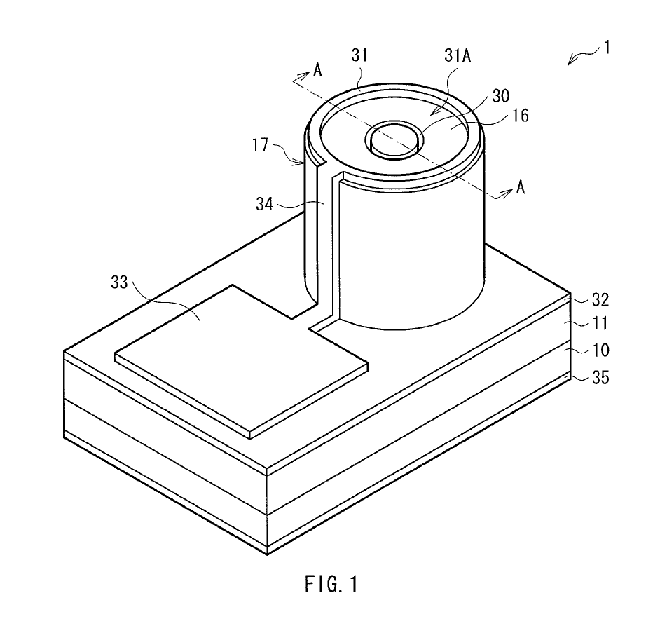

1. First embodiment (FIGS. 1 to 6)
Example in which two oxide narrowing layers are provided in an upper DBR layer.
Example in which a groove penetrating the oxide narrowing layer is provided.

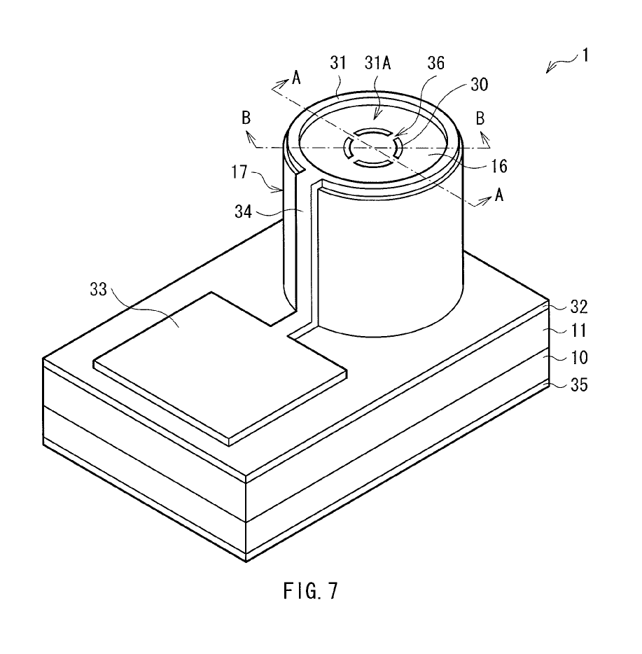

2. Modification of first embodiment (FIGS. 7 to 11)
Example in which a bridge girder is provided in the groove.

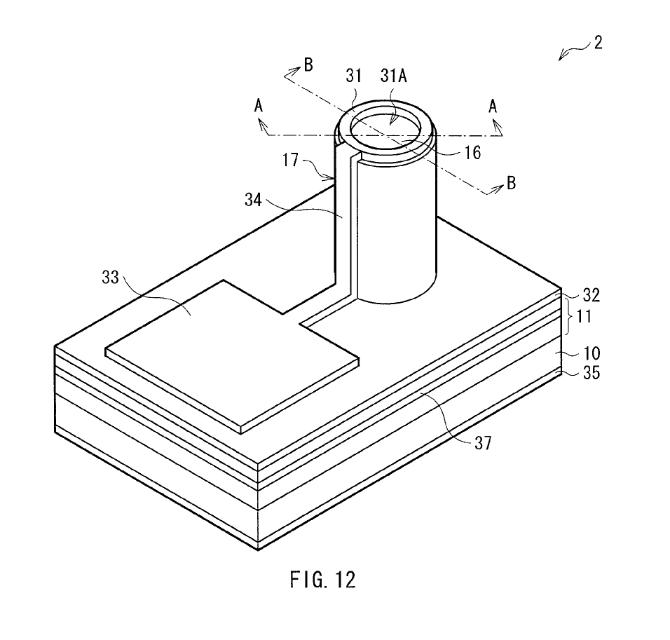

3. Second embodiment (FIGS. 12 to 16)
Example in which two oxide narrowing layers are separately provided in an upper DBR layer and a lower DBR layer.

### 1. First Embodiment

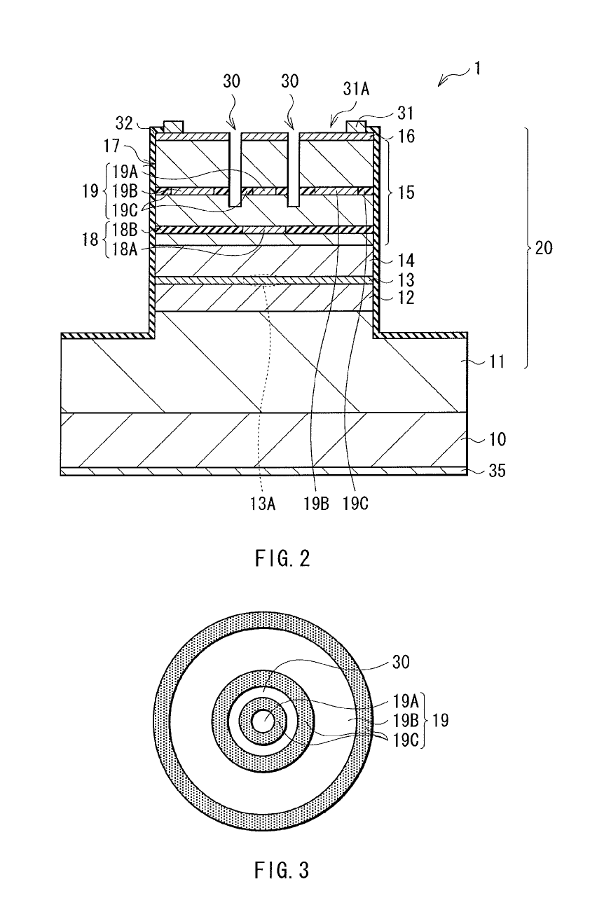

FIG. 1 perspectively illustrates a surface emitting laser diode 1 according to a first embodiment. FIG. 2 illustrates an example of the cross-sectional structure as viewed from the direction of arrow A-A of the laser diode of FIG. 1. FIG. 3 illustrates an example of the cross-sectional structure in the plane of a transverse mode adjusting layer 19 which will be described later. In addition, FIGS. 1 to 3 are the schematic illustrations, and the actual dimensions and the actual shapes are different from the dimensions and the shapes in the illustrations.

The laser diode 1 of an embodiment includes a semiconductor layer 20 formed by stacking a lower DBR layer 11, a lower spacer layer 12, an active layer 13, an upper spacer layer 14, an upper DBR layer 15, and a contact layer 16 in this order on one face side of a substrate 10. In an upper part of the semiconductor layer 20, specifically, in a part of the lower DBR layer 11, the lower spacer layer 12, the active layer 13, the upper spacer layer 14, the upper DBR layer 15, and the contact layer 16, a columnar mesa 17 is formed.

In an embodiment, the lower DBR layer 11 corresponds to a specific example of “first multilayer film reflecting mirror” of the present invention. The upper DBR layer 15 corresponds to a specific example of “second multilayer film reflecting mirror” of an embodiment.

The substrate 10 is, for example, an n-type GaAs substrate. Examples of an n-type impurity include silicon (Si) or selenium (Se). The semiconductor layer 20 is, for example, composed of an AlGaAs compound semiconductor. The term “AlGaAs compound semiconductor” denotes a compound semiconductor containing at least aluminum (Al) and gallium (Ga) in group 3B elements in the short-period type periodic table, and at least arsenic (As) in group 5B elements in the short-period type periodic table.

The lower DBR layer 11 is formed by alternately stacking a low-refractive index layer (not illustrated in the figure) and a high-refractive index layer (not illustrated in the figure). The low-refractive index layer is, for example, composed of n-type Alₓ₁Ga₁₋ₓ₁As (0<x1<1) having a thickness of λ₀/4n₁ (λ₀ is the oscillation wavelength, and n₁ is the refractive index). The high-refractive index layer is, for example, composed of n-type Alₓ₂Ga₁₋ₓ₂As (0<x2<x1) having a thickness of λ₀/4n₂ (n₂ is the refractive index).

The lower spacer layer 12 is, for example, composed of n-type Alₓ₃Ga₁₋ₓ₃As (0<x3<1). The active layer 13 is, for example, composed of undoped Alₓ₄Ga₁₋ₓ₄As (0<x4<1). In the active layer 13, a region facing a current injection region 18A which will be described later becomes a light emitting region 13A. The upper spacer layer 14 is, for example, composed of p-type Alₓ₅Ga₁₋ₓ₅As (0≦x5<1). Examples of a p-type impurity include zinc (Zn), magnesium (Mg), and beryllium (Be).

The upper DBR layer 15 is formed by alternately stacking a low-refractive index layer (not illustrated in the figure) and a high-refractive index layer (not illustrated in the figure). The low-refractive index layer is, for example, composed of p-type Alₓ₆Ga₁₋ₓ₆As (0<x6<1) having a thickness of λ₀/4n₃ (n₃ is the refractive index). The high-refractive index layer is, for example, composed of p-type Alₓ₇Ga₁₋ₓ₇As (0<x7<x6) having a thickness of λ₀/4n₄ (n₄ is the refractive index). The contact layer 16 is, for example, composed of p-type Alₓ₈Ga₁₋ₓ₈As (0<x8<1).

In the laser diode 1, for example, a current narrowing layer 18 and the transverse mode adjusting layer 19 are provided in the upper DBR layer 15. In this embodiment, the current narrowing layer 18 corresponds to a specific example of “first oxide narrowing layer” of the present application. The transverse mode adjusting layer 19 corresponds to a specific example of “second oxide narrowing layer” of the present application.

The current narrowing layer 18 is formed close to the active layer 13, in comparison with the transverse mode adjusting layer 19. In the upper DBR layer 15, in substitution for the low-refractive index layer, the current narrowing layer 18 is provided in a position of the low-refractive index layer which is, for example, several layers away from the active layer 13 side. The current narrowing layer 18 includes the current injection region 18A and the current constricting region 18B. The current injection region 18A is formed in a middle region in the plane. The current injection region 18A has a diameter larger than that of a light transmitting region 19A which will be described later. The current constricting region 18B is formed on a periphery of the current injection region 18A, that is, in an outer edge region of the current narrowing layer 18. In this embodiment, the current injection region 18A corresponds to a specific example of “first unoxidized region” of the present invention. The current constricting region 18B corresponds to a specific example of “first oxidized region” of an embodiment.

The current injection region 18A is, for example, composed of p-type Alₓ₉Ga₁₋ₓ₉As (0<x9≦1). The current constricting region 18B contains, for example, aluminum oxide (Al₂O₃), and is obtained by oxidizing highly-concentrated Al contained in a layer to be oxidized 18D from the side face, as will be described later. Thereby, the current narrowing layer 18 has a function to narrow the current. The current narrowing layer 18 may, for example, be formed inside the upper spacer layer 14, or may be formed between the upper spacer layer 14 and the upper DBR layer 15.

The transverse mode adjusting layer 19 is formed away from the active layer 13, in comparison with the current narrowing layer 18. In the upper DBR layer 15, in substitution for the low-refractive index layer, the transverse mode adjusting layer 19 is provided in a position of the low-refractive index layer which is, for example, several layers away from the current narrowing layer 18. The transverse mode adjusting layer 19 includes the light transmitting region 19A, a current injection region 19B, and a light loss region 19C. In an embodiment, the light transmitting region 19A corresponds to a specific example of “second unoxidized region” of the present invention. The current injection region 19B corresponds to a specific example of “third unoxidized region” of the present invention. The light loss region 19C corresponds to a specific example of “second oxidized region” of an embodiment.

The light transmitting region 19A is formed in a region middle in the plane, and facing the current injection region 18A in the current narrowing layer 18. The diameter of the light transmitting region 19A is smaller than that of the current injection region 18A, and is, for example, 5 μm or less. The current injection region 19B is formed in a region not facing the current injection region 18A. The current injection region 19B has an annular shape around the light transmitting region 19A. The area of the current injection region 19B is larger than that of the light transmitting region 19A. The light loss region 19C is formed on the periphery of the light transmitting region 19A and on the periphery of the current injection region 19B. Specifically, the light loss region 19C is formed between the light transmitting region 19A and a groove 30 which will be described later, between the groove 30 and the current injection region 19B, and on the periphery of the current injection region 19B, and has a shape in which a plurality of circular rings are concentrically arranged.

The light transmitting region 19A is, for example, composed of p-type Alₓ₁₀Ga₁₋ₓ₁₀As (0<x10≦1). The current injection region 19B is, for example, composed of p-type Alₓ₁₁Ga₁₋ₓ₁₁As (0<x11≦1). The current injection region 19B may be composed of the same material (same composition ratio) as the light transmitting region 19A. The light loss region 19C contains, for example, aluminum oxide (Al₂O₃), and is obtained by oxidizing highly-concentrated Al contained in a layer to be oxidized 19D from the side face, as will be described later. Thereby, the light transmitting region 19A and the light loss region 19C have functions to suppress the high-order transverse mode oscillation in the middle in the plane. The current injection region 19B has a function to transmit the current in the outer edge in the plane. That is, the transverse mode adjusting layer 19 suppresses the high-order transverse mode oscillation in the middle in the plane, and transmits the current in the outer edge in the plane.

In the case where the Al composition ratio of the light transmitting region 19A and the current injection region 19B, and the Al composition ratio of the current injection region 18A are equal to each other, the thickness (thickness in the stacking direction) of the transverse mode adjusting layer 19 is preferably smaller than the thickness of the current narrowing layer 18. In the case where the Al composition ratio of the light transmitting region 19A and the current injection region 19B is smaller than the Al composition ratio of the current injection region 18A, the thickness (thickness in the stacking direction) of the transverse mode adjusting layer 19 is preferably equal to the thickness of the current narrowing layer 18.

In an embodiment, in the upper part of the mesa 17, specifically, in the upper DBR layer 15, the groove 30 is formed. The groove 30 is formed in a region not facing the current constricting region 18B, specifically, is formed between the light transmitting region 19A and the current injection region 19B, and in the light loss region 19C. As illustrated in FIGS. 1 and 3, for example, when viewing from the top face of the mesa 17, the groove 30 has the annular shape around the current constricting region 18B (or the light transmitting region 19A). The groove 30 is formed between the light transmitting region 19A and the current injection region 19B, and has its bottom face between the current narrowing layer 18 and the transverse mode adjusting layer 19. That is, the groove 30 penetrates the transverse mode adjusting layer 19 (the light loss region 19C), and has a depth of such a degree that it is not in contact with the current narrowing layer 18.

On the top face of the mesa 17 (the top face of the contact layer 16), the annular shaped upper electrode 31 including an aperture (a light emitting exit 31A) in a region at least facing the current injection region 18A is formed. On the side face of the mesa 17 and the surface of the vicinity, an insulating layer 32 is formed. In the insulating layer 32, on the surface corresponding to the vicinity of the mesa 17, an electrode pad 33 for bonding a wire (not illustrated in the figure), and a connection section 34 are provided. The electrode pad 33 and the upper electrode 31 are electrically connected to each other through the connection section 34. On the rear face of the substrate 10, a lower electrode 35 is provided.

Here, the insulating layer 32 is, for example, composed of an insulating material such as oxide or nitride. The upper electrode 31, the electrode pad 33, and the connection section 34 are, for example, composed by stacking titanium (Ti), platinum (Pt), and gold (Au) in this order, and are electrically connected to the contact layer 16 located in the upper part of the mesa 17. The lower electrode 35 has, for example, a structure obtained by stacking an alloy of gold (Au) and germanium (Ge), nickel (Ni), and gold (Au) in this order from the substrate 10 side, and is electrically connected to the substrate 10.

(Manufacturing Method)

The laser diode 1 of an embodiment may be manufactured, for example, as follows.

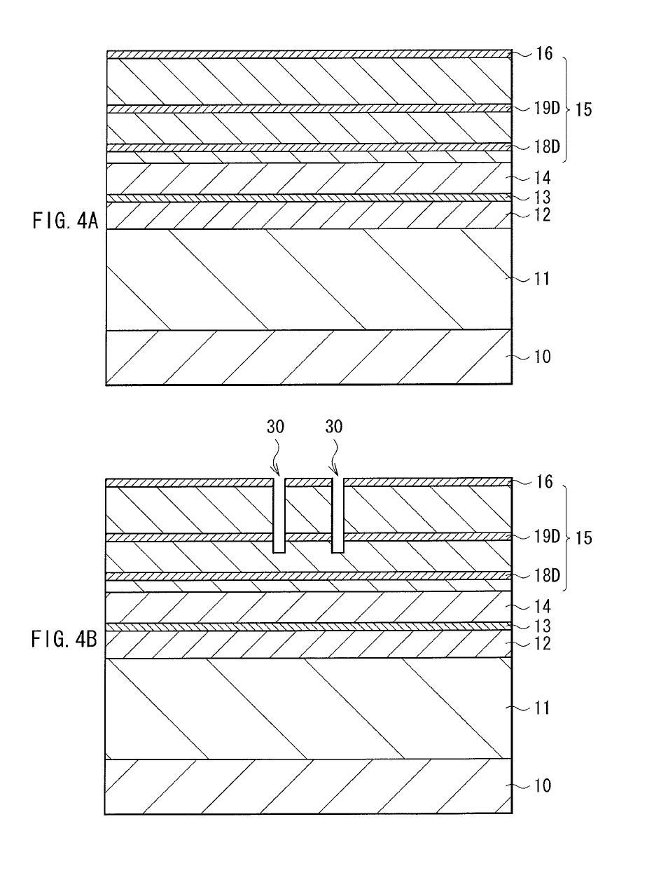

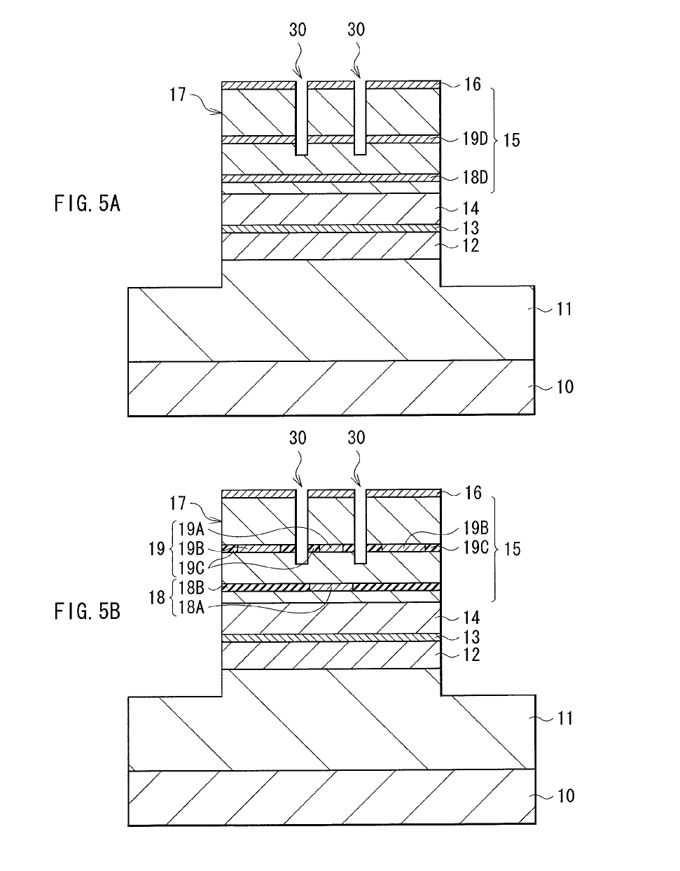

FIGS. 4A, 4B, 5A and 5B illustrate the process order of the manufacturing method. In addition, FIGS. 4A, 4B, 5A and 5B illustrate the cross-sectional structures obtained by cutting an element in the manufacturing process at the place corresponding to a line of arrow A-A of FIG. 1, respectively.

Here, the compound semiconductor layer on the GaAs substrate 10 is, for example, formed through the use of MOCVD (metal organic chemical vapor deposition) method. At this time, as materials for a III-V group compound semiconductor, for example, trimethyl aluminum (TMA), trimethyl gallium (TMG), trimethyl indium (TMIn), and arsine (AsH3) are used. As a material for a donor impurity, for example, H₂Se is used. As a material for an accepter impurity, for example, dimethyl zinc (DMZ) is used.

Specifically, first, the lower DBR layer 11, the lower spacer layer 12, the active layer 13, the upper spacer layer 14, the upper DBR layer 15, and the contact layer 16 are stacked in this order on the substrate 10 (FIG. 4A). At this time, in a part of the upper DBR layer 15, the layer to be oxidized 18D and the layer to be oxidized 19D are formed in such a manner that the layer to be oxidized 18D is located close to the active layer, in comparison with the layer to be oxidized 19D.

The layer to be oxidized 18D is a layer to become the current narrowing layer 18 by being oxidized in the oxidation process which will be described later, and contains, for example, AlAs. The layer to be oxidized 19D is a layer to become the transverse mode adjusting layer 19 by being oxidized in the oxidation process which will be described later, and contains, for example, AlAs. Here, in the case where the Al composition ratio of the layer to be oxidized 18D, and the Al composition ratio of the layer to be oxidized 19D are equal to each other, the thickness of the layer to be oxidized 19D is set to be smaller than the thickness of the layer to be oxidized 18D. In the case where the Al composition ratio of the layer to be oxidized 18D is smaller than the Al composition ratio of the layer to be oxidized 19D, the thickness of the layer to be oxidized 19D is set to be equal to, or smaller than the thickness of the layer Next, on the surface of the contact layer 16, the resist layer (not illustrated in the figure) including the aperture corresponding to the region where the groove 30 is to be formed in the subsequent process is formed. Next, for example, the contact layer 16 and the upper DBR layer 15 are selectively removed through the use of reactive ion etching (RIE) method by utilizing the resist layer as a mask. At this time, the etching is performed until penetrating the layer to be oxidized 19D, and then stopped just before reaching the layer to be oxidized 18D. Thereby, the annular shaped groove 30 having its bottom face between the layer to be oxidized 18D and the layer to be oxidized 19D is formed in the upper DBR layer 15 (FIG. 4B). At this time, the layer to be oxidized 19D is exposed to the inner wall of the groove 30. After that, the resist layer is removed to be oxidized 18D.

Next, on the surface of the contact layer 16, the circular shaped resist layer (not illustrated in the figure) having a diameter equal to that of the mesa 17 is formed. Next, for example, a part of the lower DBR layer 11, the lower spacer layer 12, the active layer 13, the upper spacer layer 14, the upper DBR layer 15, the contact layer 16, the layer to be oxidized 18D, and the layer to be oxidized 19D are selectively removed through the use of RIE method by utilizing the resist mask as a mask. Thereby, the mesa 17 is formed immediately below the circular shaped resist layer (not illustrated in the figure) (FIG. 5A). At this time, the layer to be oxidized 18D and the layer to be oxidized 19D are exposed on the side face of the mesa 17. After that, the above-described resist layer is removed.

Next, in a water-vapor atmosphere, the oxidation process is performed at a high temperature, and Al contained in the layer to be oxidized 18D and the layer to be oxidized 19D is selectively oxidized from the side face of the mesa 17 and the inner wall of the groove 30. Thereby, in the mesa 17, the outer edge region of the layer to be oxidized 18D becomes the insulating layer (aluminum oxide), and the current narrowing layer 18 is formed (FIG. 5B). Further, in the mesa 17, the outer edge region of the layer to be oxidized 19D, and the vicinity of the inner wall of the groove 30 in the layer to be oxidized 19D becomes the insulating layer (aluminum oxide), and the transverse mode adjusting layer 19 is formed (FIG. 5B).

Next, on the whole surface, for example, the insulating layer 32 (not illustrated in the figure) made of an insulating inorganic material such as silicon oxide (SiO₂) is formed. Next, after the resist layer (not illustrated in the figure) including the annular shaped aperture on the top face of the mesa 17 is formed on the whole surface, for example, the insulating layer 32 is selectively removed through the use of RIE method by utilizing the resist layer as a mask. Thereby, the aperture (not illustrated in the figure) is formed in a portion where the upper electrode 31 is to be formed. After that, the resist layer is removed.

Next, for example, the above-described metal material is staked on the whole surface through the use of vacuum evaporation method. After that, for example, the annular shaped upper electrode 31 is formed through the use of selective etching so as to fill the aperture of the insulating layer 32, and the electrode pad 33 is formed on the surface corresponding to the vicinity of the mesa 17 in the insulating layer 32. Further, the connection section 34 is formed between the upper electrode 31 and the electrode pad 33 (refer to FIG. 1). After adjusting the thickness of the substrate 10 by appropriately polishing its rear face, the lower electrode 35 is formed on the rear surface of the substrate 10 (refer to FIG. 1). In this manner, the laser diode 1 of an embodiment is manufactured.

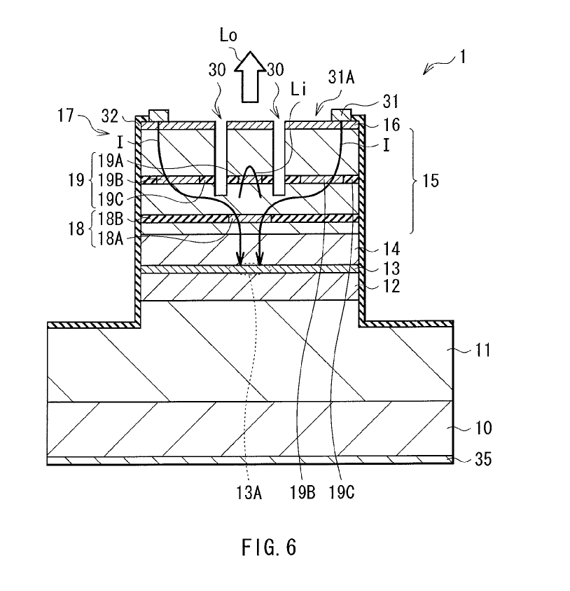

Next, with reference to FIG. 6, action and effects of the laser diode 1 of an embodiment will be described.

(Action and Effects)

In the laser diode 1 of an embodiment, when a predetermined voltage is applied between the lower electrode 35 and the upper electrode 31, a current “I” is injected into the active layer 13 through the current injection region 19B in the transverse mode adjusting layer 19, and the current injection region 18A in the current narrowing layer 18, and thereby light emission is generated by recombination of an electron and a hole. This light is reflected by the pair of the lower DBR layer 11 and the upper DBR layer 15, and the laser oscillation is generated at a predetermined wavelength. At this time, an optical field Li in the laser diode 1 senses the light transmitting region 19A and the light loss region 19C in the transverse mode adjusting layer 19. Thereby, the high-order transverse mode oscillation is suppressed and the fundamental transverse mode oscillation is generated. As a result, for example, a complete-circular shaped beam Lo is emitted outside from the light emitting exit 31A.

In an embodiment, in the middle region of the current narrowing layer 18 which is located close to the active layer 13, the current injection region 18A having the large diameter is formed, and in the middle region of the transverse mode adjusting layer 19 which is located away from the active layer 13, the light transmitting region 19A having the small diameter is formed. Thereby, the high-order transverse mode oscillation may be suppressed while increasing the volume of the light emitting region 13A of the active layer 13. Further, in this embodiment, the current injection region 19B is formed in a region other than the middle region in the transverse mode adjusting layer 19. Thereby, the current injection region 19B may serve as a current path in the transverse mode adjusting layer 19, and thus it is possible to reduce the resistance value of the transverse mode adjusting layer 19. As a result, the beam Lo having the high output and the complete-circular shape may be obtained.

### 2. Modification of First Embodiment

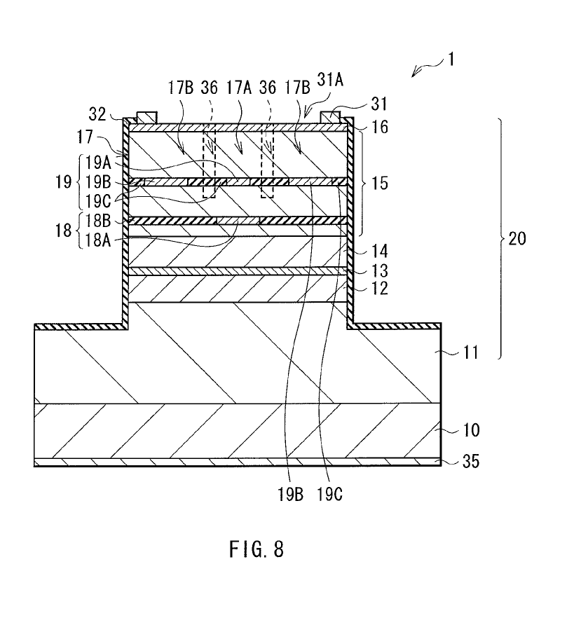

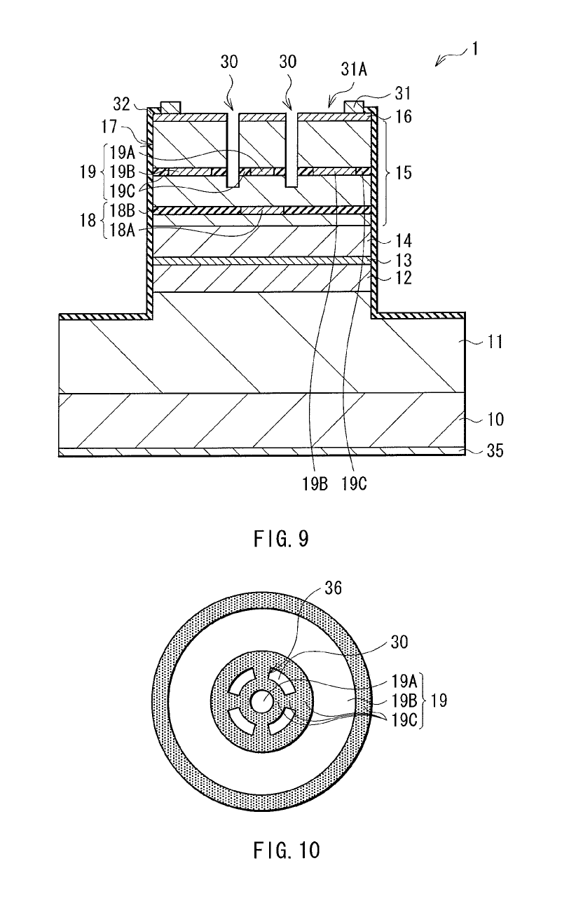

In the first embodiment, the groove 30 has the annular shape, and a portion inside the groove 30, and a portion outside the groove 30 are spatially separated in the upper DBR layer 15. However, for example, the portion inside the groove 30 and the portion outside the groove 30 may be electrically connected in the upper DBR layer 15. For example, as illustrated in FIGS. 7 to 10, a plurality of bridge girders 36 are provided inside the groove 30, and the groove 30 may be intermittently formed in the annular region around the light transmitting region 19A, when viewing from the top face of the mesa 17. FIG. 7 is a perspective view of the laser diode according to this modification. FIG. 8 is a cross-sectional view as viewed from the direction of arrow A-A of the laser diode of FIG. 7, and FIG. 9 is a cross-sectional view as viewed from the direction of arrow B-B of the laser diode of FIG. 7. FIG. 10 is a cross-sectional view in the plane of the transverse mode adjusting layer 19.

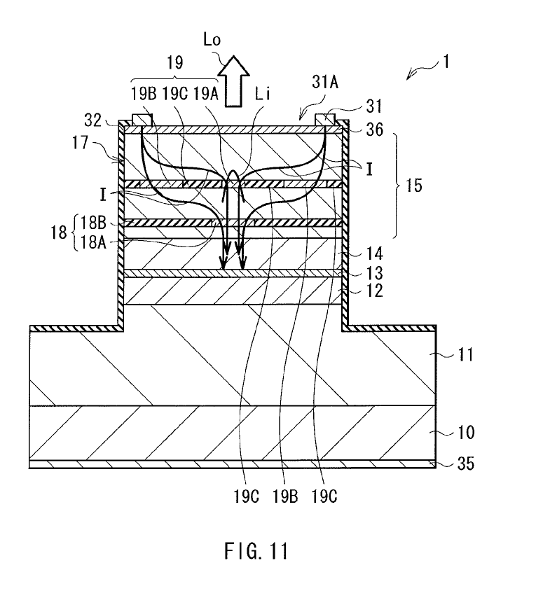

As illustrated in FIG. 8, for example, each bridge girder 36 constitutes a part of the upper DBR layer 15 and a part of the transverse mode adjusting layer 19 in the mesa 17. Each bridge birder 36 establishes the electrical connection between a portion 17A inside the groove 30, and a portion 17B outside the groove 30 in the upper DBR layer 15. Thereby, for example, as illustrated in FIG. 11, the current “I” is flown to not only the current injection region 19B, but also the light transmitting region 19A in the transverse mode adjusting layer 19, and thus it is possible to further reduce the resistance value of the transverse mode adjusting layer 19.

### 3. Second Embodiment

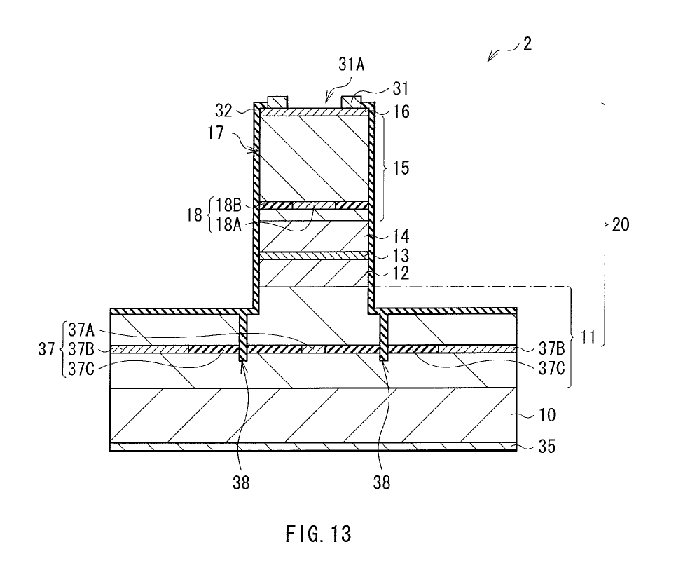

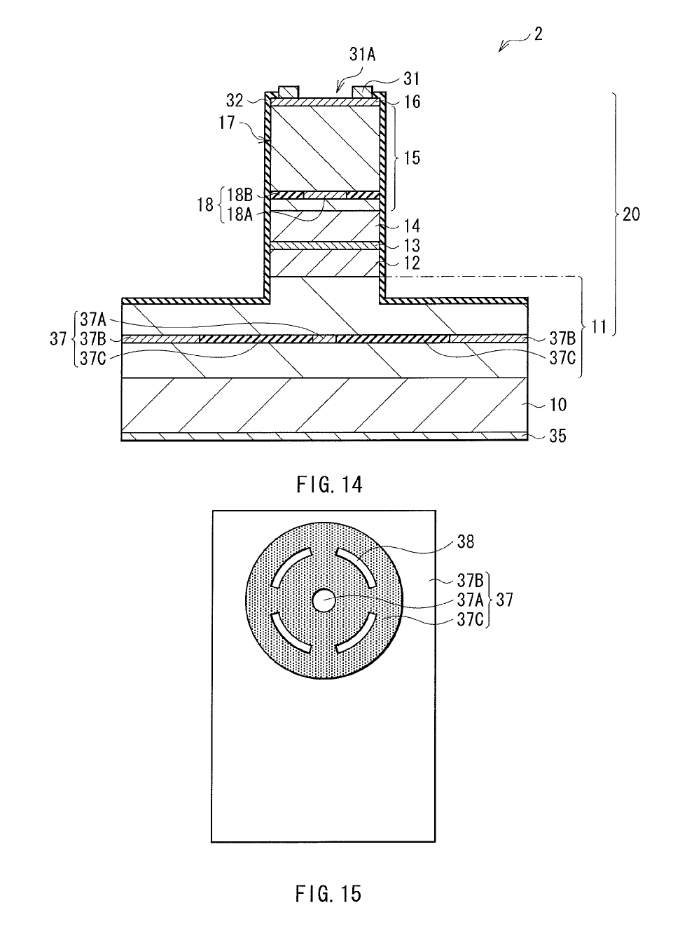

Next, a surface emitting laser diode 2 of a second embodiment will be described. FIG. 12 perspectively illustrates the laser diode 2. FIG. 13 illustrates an example of the cross-sectional structure as viewed from the direction of arrow A-A of the laser diode 2 of FIG. 12. FIG. 14 illustrates an example of the cross-sectional structure as viewed from the direction of arrow B-B of the laser diode 2 of FIG. 12. FIG. 15 illustrates an example of the cross-sectional structure in the plane of a transverse mode adjusting layer 37 which will be described later. In addition, FIGS. 12 to 15 are the schematic illustrations, and the actual dimensions and the actual shapes are different from the dimensions and the shapes in the illustrations.

In the laser diode 2 of this embodiment, the structure is different from that of the laser diode 1 of the first embodiment in that the transverse mode adjusting layer 37 is provided in substitution for the transverse mode adjusting layer 19 of the first embodiment, and a groove 38 is provided in substitution of the groove 30 of the first embodiment. Thus, hereinafter, the difference from the first embodiment will be mainly described, and the description of the points common to the first embodiment will be appropriately omitted.

In the first embodiment, although the transverse mode adjusting layer 19 is provided in the upper DBR layer 15, the transverse mode adjusting layer 37 is provided in the lower DBR layer 11. That is, the transverse mode adjusting layer 37 is provided in the DBR layer (the lower DBR layer 11) which is different from the DBR layer (the upper DBR layer 15) where the current narrowing layer 18 is provided.

In the first embodiment, although the transverse mode adjusting layer 19 is provided in the upper DBR layer 15, the transverse mode adjusting layer 37 is provided in the lower DBR layer 11. That is, the transverse mode adjusting layer 37 is provided in the DBR layer (the lower DBR layer 11) which is different from the DBR layer (the upper DBR layer 15) where the current narrowing layer 18 is provided.

The transverse mode adjusting layer 37 is formed away from the active layer 13, in comparison with the current narrowing layer 18. In substitution for a low-refractive index layer, the transverse mode adjusting layer 37 is provided in a position of the low-refractive index layer which is located away from the current narrowing layer 18 in the lower DBR layer 11. The transverse mode adjusting layer 37 includes a light transmitting region 37A, a current injection region 37B, and an light loss region 37C. In this embodiment, the light transmitting region 37A corresponds to a specific example of “second unoxidized region” of the present invention. The current injection region 37B corresponds to a specific example of “third unoxidized region” of the present invention. The light loss region 37C corresponds to a specific example of “second oxidized region” of an embodiment.

The light transmitting region 37A is formed in a region facing the current injection region 18A in the current narrowing layer 18. The diameter of the light transmitting region 37A is smaller than the diameter of the current injection region 18A, and is, for example, 5 μm or less. The current injection region 37B is formed in a region not facing the current injection region 18A. The current injection region 37B is formed on the periphery of the light loss region 37C in the plane, and its area is larger than the area of the light transmitting region 37A. The light loss region 37C is formed on the periphery of the light transmitting region 37A. Specifically, the light loss region 19C is formed between the light transmitting region 37A and the groove 38, and between the groove 38 and the current injection region 37B.

The light transmitting region 37A is, for example, composed of n-type Alₓ₁₂Ga₁₋ₓ₁₂As (0<x12≦1). The current injection region 37B is, for example, composed of n-type Alₓ₁₃Ga₁₋ₓ₁₃As (0<x13≦1). In addition, the current injection region 37B may be composed of the same material (same composition ratio) as the light transmitting region 37A. The light loss region 37C contains, for example, aluminum oxide (Al₂O₃), and is obtained by oxidizing the highly-concentrated Al contained in the layer to be oxidized (not illustrated in the figure) from the side face. Thereby, the light transmitting region 37A and the light loss region 37C have functions to suppress the high-order transverse mode oscillation immediately below the mesa 17. The current injection region 37B has a function to transmit the current on the periphery immediately below the mesa 17. That is, the transverse mode adjusting layer 37 suppresses the high-order transverse mode oscillation immediately below the mesa 17, and transmits the current on the periphery immediately below the mesa 17.

In the case where the Al composition ratio of the light transmitting region 37A and the current injection region 37B, and the Al composition ratio of the current injection region 18A are equal to each other, the thickness (thickness in the stacking direction) of the transverse mode adjusting layer 37 is preferably smaller than the thickness of the current narrowing layer 18. In the case where the Al composition ratio of the light transmitting region 37A and the current injection region 37B is smaller than the Al composition ratio of the current injection region 18A, the thickness (thickness in the stacking direction) of the transverse mode adjusting layer 37 is preferably equal to the thickness of the current narrowing layer 18.

In this embodiment, in the vicinity of the mesa 17, specifically, in the lower DBR layer 11, the groove 38 is formed. The groove 38 is formed in a region not facing the current constricting region 18B, specifically, is formed between the light transmitting region 37A and the current injection region 37B, and in the light loss region 37C. As illustrated in FIG. 15, for example, when viewing from the top face of the mesa 17, the groove 38 is intermittently formed in the annular region around the current constricting region 18B (or the light transmitting region 37A). The groove 38 is formed between the light transmitting region 37A and the current injection region 37B, and has, for example, its bottom face between the transverse mode adjusting layer 37 and the substrate 10. That is, the groove 38 penetrates, for example, the transverse mode adjusting layer 37 (the light loss region 37C), and has a depth of such a degree that it is not in contact with the substrate 10. In addition, the groove 38 may have a depth reaching the substrate 10.

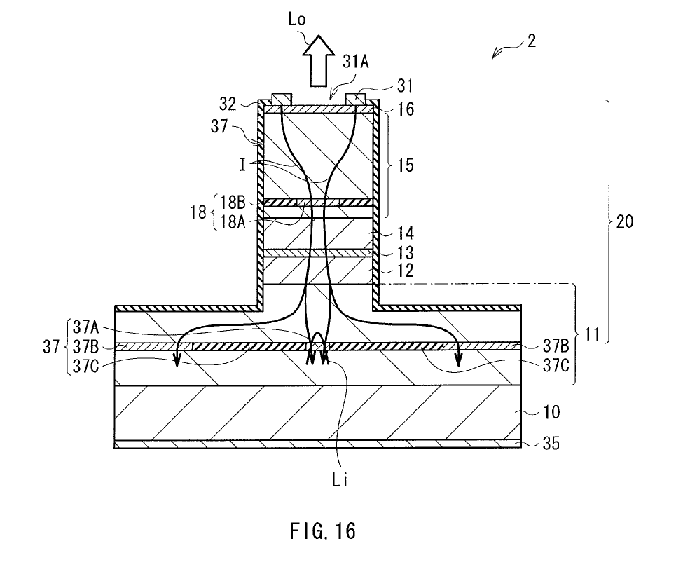

Next, with reference to FIG. 16, action and effects of the laser diode 2 of this embodiment will be described in detail.

(Action and Effects)

In the laser diode 2 of this embodiment, when a predetermined voltage is applied between the lower electrode 35 and the upper electrode 31, the current “I” is injected into the active layer 13 through the light transmitting region 37A and the current injection region 37B in the transverse mode adjusting layer 37, and the current injection region 18A in the current narrowing layer 18, and thereby light emission is generated by recombination of an electron and a hole. This light is reflected by the pair of the lower DBR layer 11 and the upper DBR layer 15, and the laser oscillation is generated at a predetermined wavelength. At this time, the optical field Li in the laser diode 2 senses the light transmitting region 37A and the light loss region 37C in the transverse mode adjusting layer 37. Thereby, the high-order transverse mode oscillation is suppressed, and the fundamental transverse mode oscillation is generated. As a result, for example, the complete-circular shaped beam Lo is emitted outside from the light emitting exit 31A.

In an embodiment, in the middle region of the current narrowing layer 18 which is located close to the active layer 13, the current injection region 18A having the large diameter is formed, and in the region facing the current injection region 18A in the transverse mode adjusting layer 37 which is located away from the active layer 13, the light transmitting region 37A having the small diameter is formed. Thereby, the high-order transverse mode oscillation may be suppressed while increasing the volume of the light emitting region 13A of the active layer 13. Further, in this embodiment, the current injection region 37B is formed in a region other than the region immediately below the mesa 17 in the transverse mode adjusting layer 37. Thereby, not only the light transmitting region 37A, but also the current injection region 37B may serve as a current path in the transverse mode adjusting layer 37, and thus it is possible to reduce the resistance value of the transverse mode adjusting layer 37. As a result, the beam Lo having the high output and the complete-circular shape may be obtained.

In the foregoing embodiments, although the present application has been described with reference to the example of the AlGaAs compound laser diode, the present application is applicable to other compound laser diodes, for example, a laser diode composed of an oxidizable compound semiconductor.

It should be understood that various changes and modifications to the presently preferred embodiments described herein will be apparent to those skilled in the art. Such changes and modifications can be made without departing from the spirit and scope of the present subject matter and without diminishing its intended advantages. It is therefore intended that such changes and modifications be covered by the appended claims.

The invention is claimed as follows:

1. A laser diode comprising:
a first multilayer film reflecting mirror, an active layer, and a second multilayer film reflecting mirror in this order; and
a first oxide narrowing layer and a second oxide narrowing layer, wherein
the first oxide narrowing layer is formed close to the active layer, in comparison with the second oxide narrowing layer, includes a first unoxidized region in a middle region in a plane, and includes a first oxidized region on a periphery of the first unoxidized region, and
the second oxide narrowing layer includes, in a region facing the first unoxidized region, a second unoxidized region having a diameter smaller than that of the first unoxidized region, includes a third unoxidized region in a region not facing the first unoxidized region, and includes a second oxidized region on a periphery of the second unoxidized region and the third unoxidized region.

2. The laser diode according to claim 1, wherein an area of the third unoxidized region is set to be larger than that of the second unoxidized region.

3. The laser diode according to claim 1, further comprising a groove between the second unoxidized region and the third unoxidized region.

4. The laser diode according to claim 3, wherein the groove has an annular shape around the second unoxidized region, or is intermittently formed in an annular region around the second unoxidized region.

5. The laser diode according to claim 4, wherein the third unoxidized region has an annular shape around the second unoxidized region.

6. The laser diode according to claim 1, wherein both of the first oxide narrowing layer and the second oxide narrowing layer are formed in the first multilayer film reflecting mirror, or the second multilayer film reflecting mirror.

7. The laser diode according to claim 1, wherein
the first oxide narrowing layer is formed in the first multilayer film reflecting mirror, or the second multilayer film reflecting mirror, and
the second oxide narrowing layer is formed in one of the first multilayer film reflecting mirror and the second multilayer film reflecting mirror, in which the first oxide narrowing layer is not formed.
